(19) United States
(12) Patent Application Publication
(10) Pub. No.: US 2021/0396714 A1
(43) Pub. Date: Dec. 23, 2021

(54) USING ULTRASOUND TO DETECT BOND-WIRE LIFT-OFF AND ESTIMATION OF DYNAMIC SAFE OPERATING AREA

(71) Applicant: The Curators of the University of Missouri, Columbia, MO (US)

(72) Inventors: Faisal KHAN, KANSAS CITY, MO (US); Abu HANIF, KANSAS CITY, MO (US); Sourov ROY, KANSAS CITY, MO (US)

(21) Appl. No.: 17/349,528

(22) Filed: Jun. 16, 2021

Related U.S. Application Data
(60) Provisional application No. 63/040,568, filed on Jun. 18, 2020.

(51) Int. Cl. G01N 29/12; H03K 17/567; G01N 29/11

(52) U.S. Cl. CPC G01N 29/12; G01N 2291/2697; G01N 29/11; H03K 17/567

(57) ABSTRACT

A method for in-situ and nonintrusive detection of one or more of bond-wire lift-off or surface degradation in insulated-gate bipolar transistor modules of a power switching device includes transmitting an ultrasonic soundwave from at least one transmitter, receiving, using at least one receiver, a reflected soundwave from the at least one insulated-gate bipolar transistor module, the reflected soundwave being a portion of the transmitted ultrasonic soundwave, using the controller to determine the frequency and amplitude of the received soundwaves, and comparing at least one of the frequency of the received soundwaves or the amplitude of the received soundwaves to known base characteristics for a new insulated-gate bipolar transistor module to determine a state of health for a power switching device including the insulated-gate bipolar transistor module being measured.

### CROSS-REFERENCE TO RELATED APPLICATIONS

This applicant claims the benefit of U.S. Provisional Application No. 63/040,568, filed Jun. 18, 2020, the entirety of which is hereby incorporated by reference.

### GOVERNMENT RIGHTS

None.

### FIELD

The present teachings relate to the determination of the degradation of power devices, and more particularly to systems and methods for investigation of a power device using techniques such as ultrasound and an estimation of the Safe Operating Area of a device.

### BACKGROUND

The statements in this section merely provide background information related to the present disclosure and may not constitute prior art.

Insulated gate bipolar transistor (IGBT) modules are one of the key elements in power converters. When large IGBT modules (e.g., modules including IGBT chips, diodes, bond wires, and associated electronics) are subjected to electrical stress and environmental factors such as temperature, humidity, vibration, and so on, natural degradation takes place, and cracks are formed in the silicon (Si) surface where bond wires are attached to the die of the module resulting in detached, cracked, or partially detached bond wires. These cracks and lift-offs eventually degrade the device performance leading to a complete failure. Performance degradation or failure have a large impact as high-power converters using IGBTs are the key elements of electric utility systems, industrial power systems, electric vehicles, and many other high-power applications. IGBT modules are typically included in these and other systems in power invertors (e.g., which can include multiple IGBT modules). Little or no down time, particularly no unexpected down time, can be tolerated in these applications as they support essential life systems for homes, businesses, transportation, and more. As a result, multiple redundant systems are commonly used in several applications. Electro-mechanical stress and environmental aging factors (mechanical vibration, heat, and radiation) form cracks in bond wires and in Si surfaces where bond wires are attached to the die. These cracks eventually degrade the performance of semiconductor switches (e.g., IGBTs or MOSFETs) and lead to failures. The power semiconductor switches are the most failure prone components in the entire inverter or converter circuit. When an IGBT module suffers from bond-wire lift-off, current crowding takes place and substrate temperature rises. In other words, the decrease in cross-sectional area caused by the interruption of the wire from the crack results in increased resistance. This eventually produces additional heat resulting from the increased resistance and causes the IGBT module (and the power switching device itself) to degrade at a faster rate leading, in turn, to a reduced operational life. Therefore, the system reliability can be significantly increased if any packaging failure such as bond wire detachment incidents can be detected and quantified in advance, and by doing this, the scheduled maintenance can be performed (e.g., ahead of schedule) to reduce the unwanted downtime.

Known ultrasound based crack or void detection techniques are either too expensive and/or requires a fluid couplant to submerge the device under test (DUT)/structure to be tested. Confocal scanning acoustic microscopy (CSAM) based state-of-health identification is very popular technique for health determination for detection in a semiconductor die and for detection in the die-attachment between the copper layer and substrate. However, this technique cannot be used in a live circuit for package level degradation detection due to the size and medium constraint of the CSAM setup. CSAM requires a wafer (e.g., component of an IGBT) to be analyzed be submerged in water. In addition, it takes a long time to scan the device under test compared to any other existing condition monitoring method. Electromagnetic acoustic transducers (EMATs) do not require any couplant, however, they require high current injections for testing, and their efficiency is not as effective as the piezo-electric transducers. In addition, the spread spectrum ultrasound technique requires highly precise transducer and couplant control to generate reasonably reliable results, and this technique has only been applied to large structures such as steel blocks.

Additionally, the safe operating area (SOA) of power switching devices is a well-known device parameter that indicates the ride-through-capability against over-voltage and over-current situations (e.g., robustness) of the device. The mean time to failure (MTTF) represents the expected lifespan of the device although it cannot adequately predict failures. When designing a power converter/inverter, it is typically assumed that the SOA remains constant, and the overall reliability of the circuit simply becomes the probability of an abnormal condition to occur, and the probability of other device failures. However, it has been found that the SOA of a semiconductor device is age-dependent and is the underlying reason for device failure especially when the device is subjected to accidental over voltage/current. In general, the SOA of a power switching device is the voltage and current conditions over which it operates without permanent damage or degradation. However, these are conservatively chosen in a circuit, meaning a power device may ride-through abnormal conditions, and the circuit can continue running normally. When a device undergoes aging, it suffers from reduced SOA, which decreases the mean time to failure (MTTF) of the device as well as the overall converter/inverter reliability. This phenomenon has been known for a long time, however the reason why remained unanswered.

### SUMMARY

This invention presents a method for estimating the remaining life of a device by investigating the level of aging of the device using techniques such as ultrasound and determining the impact of aging on the dynamic safe operating area of a device.

The present disclosure provides embodiments for a method for detecting the bond-wire lift-off in large insulated gate bipolar transistor (IGBT) power modules (including but not limited to 450A or higher) using an in-situ, nonintrusive technique. The methods described can also be used to determine surface degredation (e.g., cracks) in components of IGBT modules. In various instances, the method utilizes ultrasounic resonators for detecting the bond-wire lift-off in large IGBT power devices (e.g., including several IGBT modules). Resonators are commonly used in audio amplifiers and in the clock pulse generation units. These acoustic resonators can be used with their appropriate resonant frequency in order to detect the cracks in bond wires and bond-wire lift-off based on received soundwaves from the IGBT modules—the soundwaves received being reflected from IGBT components or being from resonating IGBT components. In the case of resonating components of the IGBT producing sound waves received by transducers, the resonating compontents can be bond wires which act similarly to the strings of a musical instrument such as Sitar. Exciting one bond wire or a plurality of bond wires can cause the bond wire(s) to resonate and cause other bond wires to resonate due to sympethetic resonance (e.g., as in strings of a Sitar).

Initial experimental results show that data generated from ultrasounic resonators can be successfully used to detect bond-wire lift-off and location of the detached bond wire. VCE (voltage accorss a collector and emitter of an IGBT) can be measured and used as an aging precursor for the power module while the IGBT is in full conduction. However, this method is only effective while the IGBT is accessible externally with no modulation applied at the gate. Therefore, in various embodiments, an alternate technique is required which can characterize IGBT regardless of its operating states. The solution can be an onboard condition monitoring circuit replacing the top cover of the IGBT module. This does not require a complete redesign of a power switching device including IGBT(s) (e.g., a converter or inverter), but rather the user or the manufacturer of a power switching device can install a diagnostic circuit board in the converter or inverter. It has been determined experimentally that ultrasound based bond-wire lift-off detection is, currently, the most suitable and direct way to characterize the bond-wire lift-off related aging level in an IGBT where the results are not operating point dependent. However, the methods described herein can be used to detect aging characteristics other than or in addition to bond-wire lift-off. For example, the methods described herein can be used to detect crack and/or void formation in surfaces of an IGBT module. The disclosed method using ultrasound resonators can continuously gather data of the IGBT power module even in-situ without compromising the converter's or inverter's normal operation. The continuous monitoring allows for early detection of degredation, continuous or periodic updating of a SOA, proactive maintenance scheduling, active control of an IGBT to remain within an updated SOA, and other advantages. Specific other advantages of the disclosed method over existing methods include: (1) The ultrasound resonator based methods are able to detect bond-wire lift-off related aging in-situ, and irrespective of the operating condition of the module or converter; (2) The disclosed methods do not require any liquid couplant, and gather data instantly and continuously; (3) The disclosed methods significantly reduce the overall cost compared to the other condition monitoring methods where additional sensors are required to measure degradation precursor parameters; and (4) The disclosed methods can be integrated with the gate driver module if properly scaled.

Therefore, it is envisioned that the successful implementation of the disclosed techniques/methods will create a seminal impact in estimating remaining life especially for IGBTs.

In various embodiments, the present disclosure provides methods and techniques for real-time estimation of the safe operating area (SOA) of a power switching device based on its state of health (SOH)/aging information. The present disclosure shows that the SOA level is a function of aging, and this interesting behavior is responsible for complicated reliability behavior in a circuit. By knowing the level of aging the dynamic SOA of the device and overall reliability can be determined.

The SOA of a metal oxide semiconductor field effect transistor (MOSFET) is bound only by the maximum drain-source voltage (breakdown voltage), the maximum drain current, and a thermal limit between them. Among these parameters, the device breakdown voltage phenomenon is heavily affected by impact ionization which is caused by avalanche multiplication and quantum mechanical tunneling of the carriers through the bandgap. This impact ionization leads to a large number of free electrons and thus a large current. A substantial amount of power is dissipated across the device resulting in the destruction of the device, and this resulting cascading effect (impact ionization) is caused. Considering impact ionization as the root cause of reduced device breakdown voltage, the following statements can be made that show how device aging accelerates the impact ionization resulting in the reduced breakdown voltage.

First, power semiconductor devices are subject to repetitive power and thermal stresses in normal operation. Owing to the difference of coefficient of thermal expansions (CTEs) in different materials/layers, cracks and voids in the die-attach layer between the Si and copper (Cu) die and at the bond-wire and chip interface are formed, resulting in bond wire lift-off. Reduced number of bond-wires and cracks and/or voids will impede the heat dissipation throughout the device, and thus thermal impedance and junction temperature increase. Furthermore, the junction temperature increase can induce hot spots and excess heat in the affected areas of the power devices. This trapped excess heat will accelerate the cascading effect of the impact ionization that will reduce the device breakdown voltage. Moreover, the localized electric field is increased in the device due to the crack and void formation which leads to accelerated impact ionization as well. Second, in addition to forming voids, cracks etc., other morphological surface defects include defects in initial solder microstructure, construction defects in an aluminum surface and substrate metallization, the formation of intermetallic compounds while the device undergoes aging, and the like. Morphological and crystallographic surface defects can cause premature reverse breakdown due to the localized enhancement of electric fields.

In order to characterize a device's SOA relative to its aging, it is important to determine the voltage breakdown since its current breakdown may not affect SOA significantly. Both destructive tests and leakage current tests can be applied to determine the device's breakdown voltage. Applying over-voltage to the device can be used to assess its breakdown voltage; one method of accomplishing this is by placing the device at the low-switch side of a boost converter with proper protection circuitry. Additionally, breakdown voltage measurement by applying a leakage current method can be done by applying an increasing reverse voltage to the device until a certain leakage current is reached that indicates that the device is in breakdown.

Based on research outcomes, it is envisioned that the probability of damage to an aged device due to accidental over voltage and over current would be different in comparison to a healthy device. A healthy switch may override multiple overstressed situations, but an aged device is less likely to do so because of its reduced SOA. This is the underlying reason for the increased failure rate of a circuit once the devices are aged. Therefore, by knowing aging, a dynamic SOA can be determined. The dynamic SOA can be utilized to give the useful remaining life of the device or the availability of a circuit (e.g., an alternative circuit can be used in the dynamic SOA is determined to be too low).

In one particular embodiment, a method disclosed herein is used for in-situ and nonintrusive detection of one or more of bond-wire lift-off or surface degradation in insulated-gate bipolar transistor modules of a power switching device. The method includes transmitting an ultrasonic soundwave from at least one transmitter, the at least one transmitter adapted and configured to transmit the ultrasonic soundwave such that the ultrasonic soundwave contacts at least one insulated-gate bipolar transistor module, the at least one transmitter being adapted and configured to be controlled by a controller. The method further includes receiving, using at least one receiver, a reflected soundwave from the at least one insulated-gate bipolar transistor module, the reflected soundwave being a portion of the transmitted ultrasonic soundwave, the at least one receiver being adapted and configured to output a signal to the controller corresponding to received soundwaves. The method still further includes using the controller to determine the frequency and amplitude of the received soundwaves, and comparing at least one of the frequency of the received soundwaves or the amplitude of the received soundwaves to known base characteristics for a new insulated-gate bipolar transistor module to determine a state of health for a power switching device including the insulated-gate bipolar transistor module being measured for at least one of bond-wire lift-off or surface degradation.

### DRAWINGS

The drawings described herein are for illustration purposes only and are not intended to limit the scope of the present teachings in any way.

FIG. 1 exemplarily illustrates Incident and reflected signals to and from an IGBT bond wire, in accordance with various embodiments of the present disclosure.

FIGS. 2A-C illustrate one embodiment for ultrasound resonator-based condition monitoring of an IGBT power module. FIG. 2A is a FF450R12ME4 IGBT dual pack module without top cover. FIG. 2B is a bottom view of a printed circuit board with resonators for condition monitoring the IGBT module. FIG. 2C is a top view of the IGBT with the printed circuit board including the transducers attached and showing transducer connectors.

FIGS. 3A-B exemplarily illustrate a healthy IGBT with no bond-wire lift-off and corresponding thermal imaging (FIG. 3A) and a damaged IBGT with at least partial damage to bond-wires and/or partial bond-wire lift-off and corresponding thermal imaging (FIG. 3B).

FIGS. 4A-4B exemplarily illustrate the measurement taken by one ultrasonic transducer of voltage over time and amplitude over frequency for a new/healthy IGBT (FIG. 4A) and a damaged IBGT (FIG. 4B).

FIGS. 5A-5B exemplarily illustrate the measurement taken by a second ultrasonic transducer of voltage over time and amplitude over frequency for a new/healthy IGBT (FIG. 5A) and a damaged IBGT (FIG. 5B).

FIGS. 6A-6B exemplarily illustrate the measurement taken by a second ultrasonic transducer of voltage over time and amplitude over frequency for a new/healthy IGBT (FIG. 6A) and a damaged IBGT (FIG. 6B).

FIG. 7 is an exemplary block diagram illustrating steps involved in determining remaining lifetime estimation of power semiconductors, in accordance with various embodiments of the present disclosure.

FIG. 8A exemplarily illustrates a schematic representation of a three phase voltage source inverter, and FIG. 8B exemplarily illustrates simulation waveforms showing accidental overvoltage, in accordance with various embodiments of the present disclosure.

FIG. 9A exemplarily illustrates an origination of cracks and voids in a power metal-oxide-semiconductor field-effect transistor (MOSFET) due to aging and FIG. 9B exemplarily illustrates wire bonding failure, in accordance with various embodiments of the present disclosure.

FIGS. 10A-10B exemplarily illustrates a bond-wire lift-off and corresponding current crowding test data generated by experiment comparing a healthy IGBT (FIG. 10A) and a damaged IGBT (FIG. 10B). The red circle shows damaged bond wires, as shown in FIG. 3, in accordance with various embodiments of the present disclosure.

FIGS. 11A-11B exemplarily illustrate a schematic (FIG. 11A) and a photograph (FIG. 11B) of an experimental set-up for an aging process, to age a as shown in FIG. 3, in accordance with various embodiments of the present disclosure.

FIG. 12 exemplarily illustrates a case temperature and drain current swing of the DUT during the power cycling test using the aging, in accordance with various embodiments of the present disclosure.

FIGS. 13A-13B exemplarily illustrate a schematic diagram (FIG. 13A) and a photograph (FIG. 13B) of the experimental set-up for determining maximum safe operating voltage of an IGBT device, in accordance with various embodiments of the present disclosure.

FIG. 14 exemplarily illustrates experimental results showing reduced maximum safe operating voltage of an aged MOSFET, with Vmaximum=maximum safe operating voltage, in accordance with various embodiments of the present disclosure.

Corresponding reference numerals indicate corresponding parts throughout the several views of drawings.

### DETAILED DESCRIPTION

The following description is merely exemplary in nature and is in no way intended to limit the present teachings, application, or uses. Throughout this specification, like reference numerals will be used to refer to like elements. Additionally, the embodiments disclosed below are not intended to be exhaustive or to limit the invention to the precise forms disclosed in the following detailed description. Rather, the embodiments are chosen and described so that others skilled in the art can utilize their teachings. As well, it should be understood that the drawings are intended to illustrate and plainly disclose presently envisioned embodiments to one of skill in the art, but are not intended to be manufacturing level drawings or renditions of final products and may include simplified conceptual views to facilitate understanding or explanation. As well, the relative size and arrangement of the components may differ from that shown and still operate within the spirit of the invention.

As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to practice the disclosure and are not intended to limit the scope of the appended claims.

Unless otherwise defined, all technical and scientific terms used herein have the same meaning as commonly understood by one of ordinary skill in the art to which this disclosure belongs. The terminology used herein is for the purpose of describing particular example embodiments only and is not intended to be limiting. As used herein, the singular forms “a”, “an”, and “the” may be intended to include the plural forms as well, unless the context clearly indicates otherwise. The terms “comprises”, “comprising”, “including”, and “having” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps can be employed.

When an element, object, device, apparatus, component, region or section, etc., is referred to as being “on”, “engaged to or with”, “connected to or with”, or “coupled to or with” another element, object, device, apparatus, component, region or section, etc., it can be directly on, engaged, connected or coupled to or with the other element, object, device, apparatus, component, region or section, etc., or intervening elements, objects, devices, apparatuses, components, regions or sections, etc., can be present. In contrast, when an element, object, device, apparatus, component, region or section, etc., is referred to as being “directly on”, “directly engaged to”, “directly connected to”, or “directly coupled to” another element, object, device, apparatus, component, region or section, etc., there may be no intervening elements, objects, devices, apparatuses, components, regions or sections, etc., present. Other words used to describe the relationship between elements, objects, devices, apparatuses, components, regions or sections, etc., should be interpreted in a like fashion (e.g., “between” versus “directly between”, “adjacent” versus “directly adjacent”, etc.).

As used herein the phrase “operably connected to” will be understood to mean two are more elements, objects, devices, apparatuses, components, etc., that are directly or indirectly connected to each other in an operational and/or cooperative manner such that operation or function of at least one of the elements, objects, devices, apparatuses, components, etc., imparts are causes operation or function of at least one other of the elements, objects, devices, apparatuses, components, etc. Such imparting or causing of operation or function can be unilateral or bilateral.

As used herein, the term “and/or” includes any and all combinations of one or more of the associated listed items. For example, A and/or B includes A alone, or B alone, or both A and B.

Although the terms first, second, third, etc. can be used herein to describe various elements, objects, devices, apparatuses, components, regions or sections, etc., these elements, objects, devices, apparatuses, components, regions or sections, etc., should not be limited by these terms. These terms may be used only to distinguish one element, object, device, apparatus, component, region or section, etc., from another element, object, device, apparatus, component, region or section, etc., and do not necessarily imply a sequence or order unless clearly indicated by the context.

Moreover, it will be understood that various directions such as “upper”, “lower”, “bottom”, “top”, “left”, “right”, “first”, “second” and so forth are made only with respect to explanation in conjunction with the drawings, and that components may be oriented differently, for instance, during transportation and manufacturing as well as operation. Because many varying and different embodiments may be made within the scope of the concept(s) taught herein, and because many modifications may be made in the embodiments described herein, it is to be understood that the details herein are to be interpreted as illustrative and non-limiting.

The apparatuses/systems and methods described herein can be implemented at least in part by one or more computer program products comprising one or more non-transitory, tangible, computer-readable mediums storing computer programs with instructions that may be performed by one or more processors. The computer programs may include processor executable instructions and/or instructions that may be translated or otherwise interpreted by a processor such that the processor may perform the instructions. The computer programs can also include stored data. Non-limiting examples of the non-transitory, tangible, computer readable medium are nonvolatile memory, magnetic storage, and optical storage.

As used herein, the term module, circuit, or controller can refer to, be part of, or include an application specific integrated circuit (ASIC); an electronic circuit; a combinational logic circuit; a field programmable gate array (FPGA); a processor (shared, dedicated, or group) that performs instructions included in code, including for example, execution of executable code instructions and/or interpretation/translation of uncompiled code; other suitable hardware components that provide the described functionality; or a combination of some or all of the above, such as in a system-on-chip. The term module can include memory (shared, dedicated, or group) that stores code executed by the processor.

The term code, as used herein, can include software, firmware, and/or microcode, and can refer to one or more programs, routines, functions, classes, and/or objects. The term shared, as used herein, means that some or all code from multiple modules can be executed using a single (shared) processor. In addition, some or all code from multiple modules can be stored by a single (shared) memory. The term group, as used above, means that some or all code from a single module can be executed using a group of processors. In addition, some or all code from a single module can be stored using a group of memories.

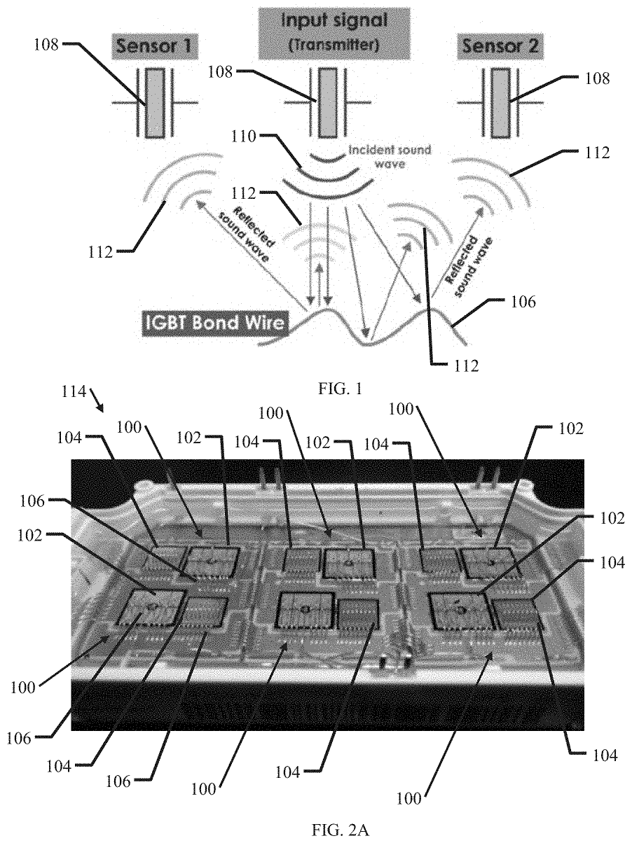

Referring now to FIGS. 1 through 6B, ultrasonic transducers are used to measure degradation of an IGBT module 100 (e.g., including an IGBT chip 102, diode 104, bond-wire(s) 106) or like device. The ultrasonic transducers 108 can function using piezoelectric crystals of the type that have a wide range of applications including, but not limited to, ultrasound resonators, crystal oscillators, dc-dc converters (as MEMS), etc. Ultrasonic resonators can be used both as the transmitter and receiver. As shown in FIG. 1, a single transducer 108 can be used as a transmitter and one or more other transducers can be used as receivers.

Generally, when two mediums have different acoustic impedances (Z), part of a transmitted wave 110 impacting the mediums transmits through the interface into the second medium and the rest reflects back to the same medium as a reflected wave 112. This difference in Z is commonly referred to as the impedance mismatch, and the amount of reflection depends on the impedance contrast between the two mediums. The greater the impedance mismatch, the greater the percentage of energy that will be reflected at the interface or boundary between one medium and another. If the acoustic impedances of two medium is said to be Z₁ and Z₂ then the following equation can be used to calculate the reflection coefficient (R).

$$R = {( \frac{{Z}_{2} - {Z}_{1}}{{Z}_{2} + {Z}_{1}} )}^{2}$$

The transmitting ultrasonic transducer 108 can be mounted in such a way that the transmitted ultrasonic beam/wave can be impinged on a surface crack and voids in a solid at an incident angle of θ, the emitted energy distribution (returning wave) will be the result of contribution from two components. A first component is the diffraction of a ray at the tip of a crack creating a spherical wave front from the mode conversion, and the second component is the wave reflected from the mouth of the surface crack. The location and the depth (d) of the surface crack or void can be determined as follows:

$$d = \frac{Δ l}{2 cos θ} = \frac{{v}_{s} Δ t}{2 cos θ}$$

where vs denotes the velocity of the incident wave; At is the difference of the arrival times and Al is the path difference between these two wave components. It is important to note that based on the incident angle (θ) and the depth and location of the surface defects, the position of the receiver sensor (transducer 108) needs to be adjusted to capture the reflected signal components of maximum energy. Considering this, the optimized number of sensors (transducers 108) along with their optimum locations can be determined for each IGBT chip in order to determine their corresponding surface defects. These relationships can be used to adopt the method and systems described herein to work with different power switching equipment including different numbers of IGBTs and different locations of IGBTs.

For various IGBT modules (for example the Infineon™ FF450R12ME4 module) the bond wires are encapsulated in a silicone gel layer to prevent moistures to come in contact with the die. Therefore, a contrast in acoustic impedance exists between the gel layer (Z₂) and the bond wires (Z₁). Once there is a crack or lift off associated with these bond wires, the acoustic impedance of the bond wires (Z₁) is likely to differ from that of a new module. Therefore, the reflection coefficient for a healthy IGBT module will have a different magnitude than the corresponding reflection of an aged module. Using this phenomenon, in an example experiment it was possible to identify the bond-wire lift-off related device degradation using the ultrasound resonators as disclosed herein. Table 1, below, shows the acoustic behavior of the IGBT gel layer, and the ultrasound wave attenuated about 19% to propagate through the gel layer.

TABLE 1

| | | Acoustic | | Output power of | | | |
|---|---|---|---|---|---|---|---|
| Density of | Acoustic | impedance | Attenuation | the resonator at | Thickness | Attenuated | |
| silicone | Velocity in | of gel layer | coefficient | 100mvp-p input | of the gel | amplitude | Total |
| gel (ρ) | gel layer(v) | (Z = ρv) | in gel layer | voltage (A₀ = | layer ( [symbol] ) | (A(z) = A₀ | attenuation |
| Kgm [symbol] | ms⁻¹ | MRayls | ( [symbol] ) dBcm⁻¹ | $10 log \text{?} ) dB$ | cm | $e \text{?} )$ | (dB) |
| 700 | 1490 | 1.043 | 2.175 | 36.81 | 0.8 | 29.88 | 6.93 |
| | | | | | | | (18.82%) |

[symbol]

indicates data missing or illegible when filed

The reflected signal experienced a maximum 19% attenuation until it reaches the receiver transducer 108. Because of the curved shapes of the bond wire, a top edge of the wire penetrated half way inside the gel layer, thus making the total travel distance through the gel layer equal to 0.5X+0.5X=1.0X, where X is the thickness of the gel layer, for example, X=8 mm. Therefore, in this experimental instance, the total attenuation was only 6.93 dB, and the input energy from the ultrasound sensors were sufficient to interact with the bond wires and to reflect back to the receiver sensors (transducers 108). FIG. 1 shows several interactions between the acoustic wave and a bond wire including few possible reflection paths. The input signal, an ultrasonic wave, is provided (e.g., transmitted) by a single transducer 108 (transmitter). The transmitted wave is reflected by the bond-wire 106 at one or more locations on the bond-wire 106. The reflected ultrasonic wave(s) are received by one or more transducers 108 operating as receivers only (sensor 1 and sensor 2).

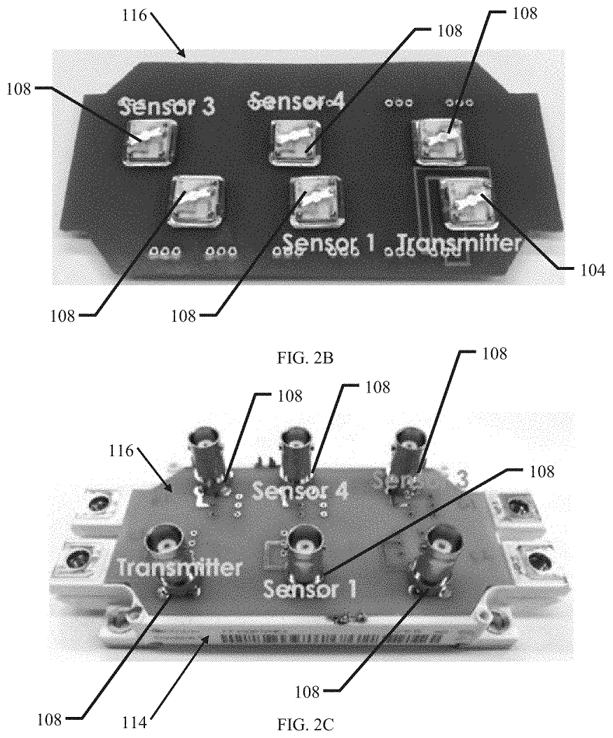

In the case of sympathetic resonance, the input signal (transmitted ultrasonic wave) excites one or more bond-wires 106 which then vibrate as a result and excite other nearby bond-wires 106 (e.g., nearby bond-wires 106 being shown in FIG. 2A). This causes nearby bond-wires 106 to vibrate in a fundamental, harmonic, or sub-harmonic frequency. Generally, this is a result of sympathetic resonance or vibration can be defined as “resonant or near-resonant response of a mechanical or acoustical system excited by energy from an adjoining system in steady-state vibration. Several musical instruments use sympathetic resonance in order to produce characteristic sounds. These instruments include but are not limited to Sitar, Sarangi, Viola D'amore, Baryton, Sarod, Ukelin, and so on. The basic principle is to excite one string of any of these instruments, and other strings will resonate at their either fundamental or harmonic frequencies. The strings of such musical instruments are usually connected to a vibrating body, known as the soundboard. This soundboard is made of multiple materials with compound shapes. This helps in generating efficient sound propagation. Thus, creating an effective coupling between the soundboard and the strings, it is possible to vibrate one string if another string is excited. This phenomenon is referred as sympathetic resonance.

Sympathetic resonance is not only important in musical applications but also plays a vital role in the field applications of electric machineries. For example, if two or more motors are installed on the same base, then vibration energy may transfer to the nearby motor/machine and may damage the machine even if it is in standby mode. This will only occur if the vibrating frequency of the running machine matches the resonance frequency of the nearby motor, which in other words is due to the sympathetic resonance. So, the vibration signature, both the frequency and amplitude, is useful in fault diagnosis of the electric motors.

To detect the bond wire related degradation using ultrasonic resonators, the resonant frequency of the bond wires in the IGBT module needs to be determined. A relationship exists between the resonant frequency and the length of the bond wire. In order to detect damage in a bond wire two things play important role: the length of the bond wires and the resonant frequency and the magnitude of resonance. The following two equations can be referred to explain this relationship:

$$ω = \frac{{k}_{1} d}{{l}^{2}} \qquad a = {k}_{2} {l}^{4}$$

where, ω=resonant frequency=2πf, k1=a constant based on bond wire material, d=diameter of the bond wire, a=resonant amplitude, and k2=a constant based on bond wire material.

According to these two above mentioned equations, a longer bond-wire results in a lower resonant frequency (f∝1/I²) but a higher resonant magnitude (a∝I⁴). Fortunately, all of the 48 bond wires in the FF450R12ME4 power switching device are of equal length. Therefore, the resonators could be operated at a specific frequency to initiate the resonance in the bond-wires 106 instead of sweeping the frequency. However, it should be noted that the resonant frequency could vary from module to module depending on the package dimensions. There could also be variation owing to bond-wires of different lengths. In such cases, multiple transducers can be used to transmit ultrasonic waves at different frequencies, each corresponding to the resonant frequency of a different length bond-wire thus allowing for the measurement/determination of degradation for different bond-wires within the same IGBT module or power switching device.

Importantly, the resonant magnitude and/or resonant frequency changes if there is bond wire lift-off or a crack present in an IGBT module (e.g., a crack in a bond-wire 106, connection pad, substrate, or the like). Any detached or semi-detached bond-wire will perturb the sympathetic resonance, and any crack or void will alter the tension in the bond wire resulting in altered resonance signature. This change can be detected and used to identified device aging/degradation for use in updating a SOA for the device. Resonators (e.g., transducers 108) can be excited at other harmonic and sub-harmonic frequencies which will enable the recordation of the vibration signatures of the affected (e.g., degraded or damaged) bond-wires. Thus, it is possible to differentiate between a healthy and an aged IGBT module. In addition, it is possible to create, through experimentation, a library of the resonator data for healthy devices (i.e., including the resonant frequencies and resonant magnitudes), and then compare measurement results to the library to determine if there is damage/degradation to bond-wires and/or other components of an IGBT module or power switching device in its entirety.

In addition to complete bond-wire failure, this technique can detect any surface level degradation. The bond-wires attached to the substrate have a certain tension, and this tension amount has an impact on the resonance magnitude. Any crack or void at the bond-wire and substrate interface will reduce the wire tension resulting in a change in resonance frequency. This change in resonance frequency can be measured and compared to a base measurement for a new power switching device or IGBT. Any difference in the comparison can indicate degradation and can be used to update a SOA for the device.

### Experimental Setup and Results

Inside large IGBT modules (e.g., power switching devices such as the power switching device 114 shown in FIG. 2A), the actual semiconductor devices (e.g., IGBTs 102, diodes 104, etc.) are physically connected by multiple bond-wires 106. For example, the methods described herein have been validated using an Infineon™ dual pack IGBT module (FF450R12ME4) 114. For this section discussing experimental results, the Infineon™ dual pack IGBT module (FF450R12ME4) was the device under test (DUT). It should be understood that the methods and apparatus described herein, in this section and others, apply generally to different power switching devices 114 as well and are not limited to this specific device. The Infineon™ dual pack IGBT module has six IGBT devices 102 (three top and three bottom) and their corresponding free-wheeling diodes 104. Each IGBT 102 and diode 104 pair is interconnected with eight bond wires, therefore, the entire module has total of 48 bond wires. There can be additional bond-wires connecting the diodes 104 to other equipment (e.g., a substrate, connecting the substrate to a terminal, etc.). Any of these bond-wires, and/or the substrates to which they attach, can be measured using the methods and techniques described herein.

At first, a healthy IGBT module (FF450R12ME4) was characterized using multiple ultrasound resonators. Tests were conducted at room temperature and data were recorded using a Keysight™ oscilloscope. The plastic backplate of the IGBT was removed (as shown in FIG. 2A), and a sensing device 116 (shown in FIGS. 2B-2C) is attached in its place (shown in FIG. 2C). The sensing device 116 includes a printed circuit board (PCB) having six (6) 25 MHz acoustic resonators (i.e., transducers 108). The resonators/transducers 108 are piezoelectric transducers. In alternative embodiments, the transducers 108 are capacitive transducers, magnetostriction transducers, microelectromechanical systems transducers, or any other suitable transducer for transmitting and receiving ultrasonic waves. It should be noted that in some embodiments, dedicated transmitter(s) and/or dedicated receiver(s) can be used instead of transducers.

It should be understood that the resonators can operate at a frequency of substantially 25 MHz but that natural variation can be present. For example, the resonators can operate within a window of 24 MHz to 26 MHz, 24.95 MHz, or other variation such that the resonators still operate at substantially 25 MHz. The resonators used as receivers can be adapted and configured to receive a specific frequency, e.g., that substantially matches that of the transmitter (24 MHz to 26 MHz). Such tuned receivers can have a specific geometry or other features to attune them to receive at the specific frequency. Alternatively, the receivers can be adapted and configured to receive a variety of frequencies with no specific focus on a particular ultrasonic frequency. In alternative embodiments, the resonators operate at a frequency of substantially 35 MHz (e.g., 34 MHz to 36 MHz).

The sensing device 116 was used in place of the backplate of existing power switching device 114 (as shown in the FIG. 2B). In this experimental embodiment, out of these six resonators 108, one was used as the transmitter (as labeled), and the remaining five resonators 108 were used as receivers. The location of each of these resonators were consistent with the six IGBTs 102 inside the package of the power switching device 114 (the multiple IGBT package is shown in FIG. 2A). In other embodiments that differ from this experimental setup, other configurations of transducers 108 can be used for making measurements. In one embodiment, a single transducer 108 both transmits and receives and measures a single IGBT module 102. Multiple transducers are used for electronic switching devices 114 that include multiple IGBTs 102, with one transducer 108 for each IGBT 102. The transducers 108 can be multiplexed to target measurement to specific IGBT modules 102. In another embodiment, a single transducer 108 is used for transmitting and receiving, or a single pair of transducers 108 (one for transmitting, one for receiving). Multiple IGBT modules 102 can be measured using the single transducer 108 or single pair of transducers 108. Knowing the position of the transducer/transducer pair and the geometry of the device 114 packaging, the time from transmission to reception can be used to identify which IGBT module 102 corresponds to each received wave. This principle can also be used to identify specific components being measured using other configurations of transducers 108. In still further embodiments, other numbers of transmitters and receivers can be used.

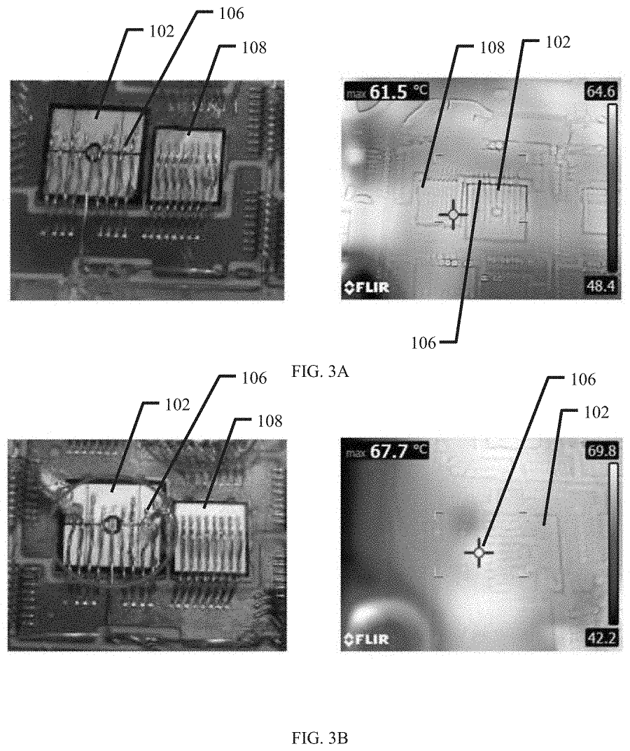

In order to test the detection methods described herein, it was necessary to create damaged IGBTs in order to determine if the damage could be measured. To create bond-wire lift-off incidents in a controlled manner, multiple bond wires were disconnected in several locations rather than aging the IGBT using an accelerated aging station. This was intentionally done to avoid uncertainty and quick turn-around time to validate our theory. A thermal camera was used to monitor the current crowding due to damaged bond wires of a device inside the package. FIG. 3A shows a healthy IGBT device/module 102 with all eight (8) bond wires intact. For this device the corresponding thermal image was uniform without any significant hotspot. FIG. 3B shows a photograph of the IGBT device 102 with 3 bond-wires 106 detached, and the corresponding thermal image shows hotspot formation.

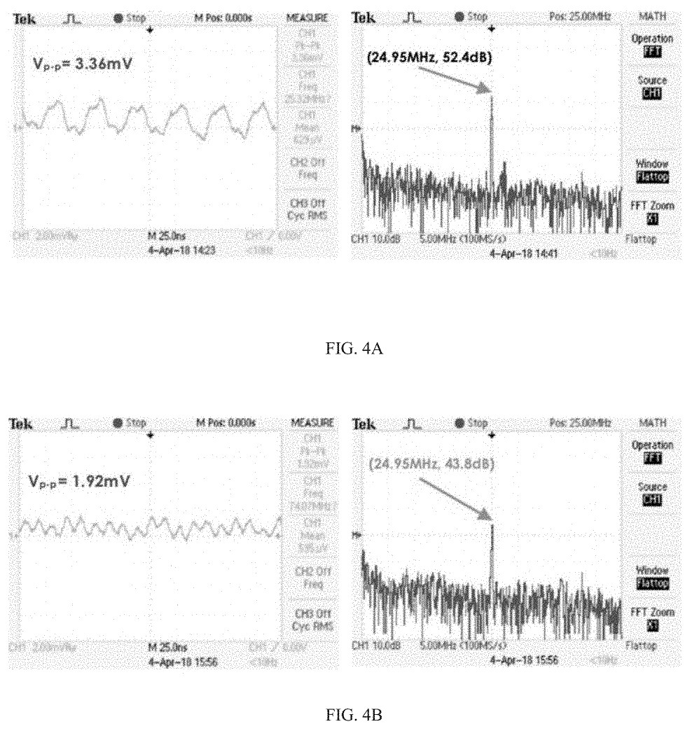

FIGS. 4A-6B show the ultrasonic measurement results obtained from the onboard sensors shown in FIGS. 2A-2B and disclosed herein. FIGS. 4A-4B shows data from Sensor 1 (shown in FIGS. 2B-2C) in both voltage/time domain and amplitude/frequency domain. Particularly, FIG. 4A shows the voltage/time domain data and amplitude/frequency domain data with all bond-wires intact. In other words, the data corresponds to a healthy/new IGBT module 102 and device 114. FIG. 4B shows the voltage/time domain data and amplitude/frequency domain data for an aged/degraded/damaged IGBT module 102 (with three bond-wires removed) of the device 114.

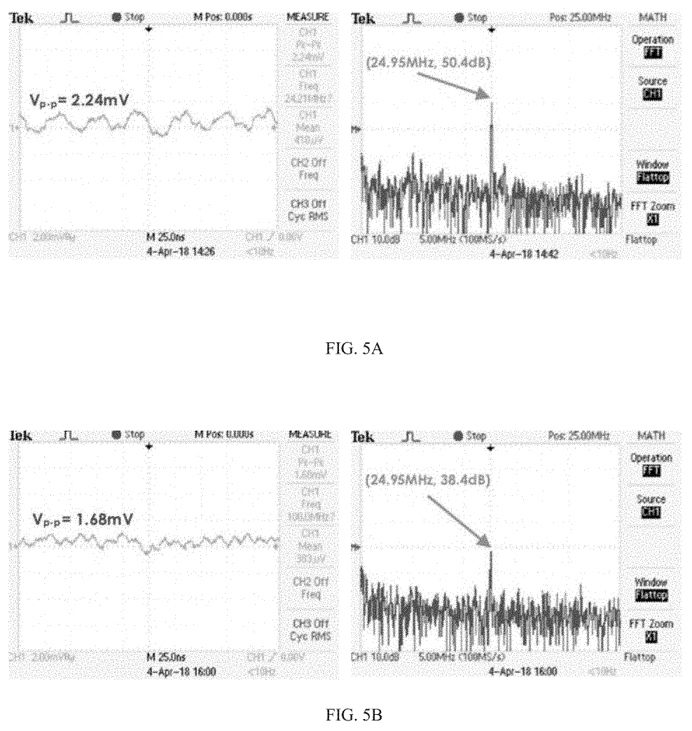

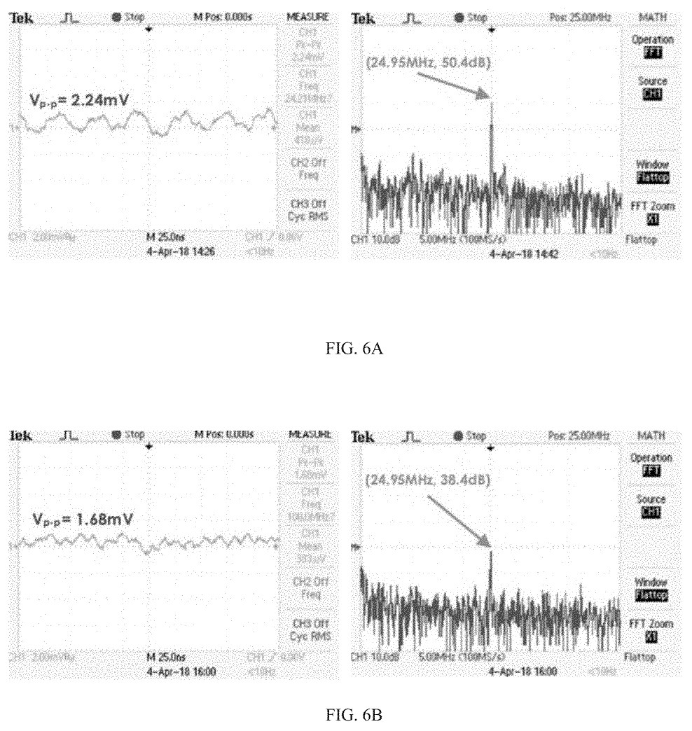

FIGS. 5A-5B show the same data for Sensor 4 (shown in FIGS. 2A-2B). FIG. 5A shows the voltage/time domain data and amplitude/frequency domain data with all bond-wires intact. In other words, the data corresponds to a healthy/new IGBT module 102 and device 114. FIG. 5B shows the voltage/time domain data and amplitude/frequency domain data for an aged/degraded/damaged IGBT module 102 (with three bond-wires removed) of the device 114. It is evident that for any physical damage at any specific location, at least two sensors (Sensors 1 and 4) produce reduced time and frequency domain output compared to a healthy module. In other words, damage, degradation, bond-wire lift-off, partial bond-wire lift-off, cracks, surface damage, and the like can be detected as a result of a transducer response showing a decreased voltage response over time and/or a decreased amplitude response at a specific frequency or frequencies in comparison to a healthy IGBT module, component, and/or power switching device. A similar response was observed from Sensor 3 (shown in FIGS. 2B-2C). This response, a decrease in voltage and decrease in amplitude at the ultrasonic frequency for a damaged device, is shown in FIGS. 6A-6B. Sensor 1 detects a reduction of 8.4 dB in the damaged IGBT module (as shown in FIGS. 4A-4B), and sensor 4 detects an even larger 12 dB in the amplitude/frequency domain output (as shown in FIGS. 5A-5B). These reduced amplitudes are the clear indication of the IGBT's 102 bond-wire 106 lift-off phenomenon. Given the similar responses of sensor 3 (FIG. 6) and sensor 4 (FIG. 5), in some embodiments one of sensor 3 and sensor 4 can be omitted.

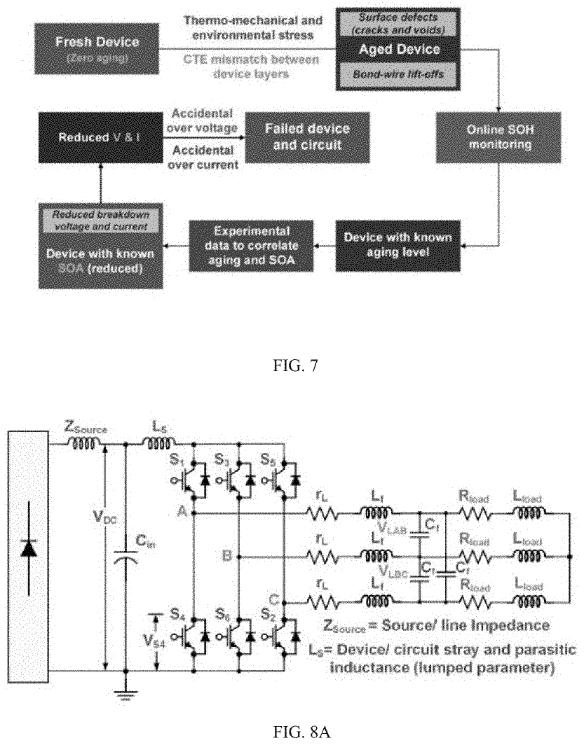

Referring now to FIGS. 7 through 14, safe operating area (SOA) is a critical parameter to design a power converter/inverter circuit, and it indicates the robustness of the device 114. The device 114 including one or more IGBTs for use in converting/inverting electrical power. SOA defines the current-voltage boundary in which a power semiconductor device can be safely operated. During abnormal operating conditions, a power electronic circuit may experience high-voltage and high-current beyond normal operating values. Typically, the SOA of a device is conservatively chosen in a circuit, meaning a certain percentage of tolerance is initially allocated so that the power device may ride through accidental over voltage/current situations before a complete failure (either short or open) takes place. In general, it has been assumed, incorrectly, that the SOA remains constant, and the overall reliability of the circuit simply becomes the probability of an abnormal condition to occur, and the probability of other device failures. Although power converters/inverters are comprised of multiple elements, power switching devices (e.g., MOSFETs, IGBTs, and the like) are the most vulnerable components in a power converter system. Any thermal or electrical stress factors degrade the performance of semiconductor switches and eventually lead to failures. According to study and experimentation, SOA of any semiconductor device such as MOSFET or IGBT goes down with an increased level of aging, and this observation explains why the reliability of an entire circuit exponentially drops with aging. Thus, mean-time-to-failure (MTTF) decreases with the increased aging of the converter/inverter switches.

According to the existing literature and research activities, the ultimate goal of determining the SOA is to accurately predict when an IGBT, MOSFET or other power converter switches are likely to fail. Therefore, there are substantial flaws in this model as the SOA is not updated over time in consideration of device aging. Therefore, online state-of-health (SOH) monitoring in semiconductor devices need to be performed to measure level of aging, which can be used to identify the dynamic SOA, and thus, to predict the MTTF of the overall circuit. SOH estimation in power switches is a fairly well-established area, although better accuracy is still needed. Variations in electrical parameters (i.e. ON-state channel resistance, R_{DS(ON)}, collector-emitter voltage in saturation, V_{CE(SAT)}, etc.) along with thermal parameters (i.e. thermal resistance, R_{TH}) carry the degradation information in most of the chip and package-related failures such as gate structure degradation, wire-bond lift-offs, solder fatigues, and so on. The research to date has been primarily focused on measuring and characterizing the device degradation using both direct and indirect methods of measuring the above-mentioned aging precursors. These methods suffer from the flaws previously discussed above. The method described herein using ultrasonic transducers provides significant advantages over these methods and allows for dynamic updating of a device SOA.

The present disclosure show that the following statements can be made:
a) Accidental over voltage and current can damage both a healthy and aged device although the probabilities would be different. A healthy (new) switch may override multiple overstressed situations, but an aged device is less likely to override those anomalies without failing. This is the underlying reason of increased failure rate of a circuit once the devices are aged.
b) In all calculations, it has been assumed the SOA of a device to be constant. According to our recent test results, SOA changes with aging, i.e. SOA goes down with higher aging.
c) The remaining life of a switch is a function of SOA.
d) Therefore, remaining life goes down with higher aging.
e) For high power devices such as MOSFETs and IGBTs, aging is caused by bond wire detachment, cracks in the bond wire interface, voids in the wafer and other packaging issues. By knowing the device health using online condition monitoring such as ultrasound-based bond-wire lift-off monitoring, it is possible to accurately estimate aging.
f) Therefore, by accomplishing (e), we can estimate aging. By knowing aging, we can determine dynamic SOA. The correlation between aging and dynamic SOA gives us the useful remaining life of the device or the availability of a circuit (if a particular circuit is more aged than another and a high load is anticipated the healthier circuit can be selected and the less healthy circuit made unavailable).

FIG. 7 demonstrates the above-mentioned steps in a chronological manner. In summary, the methods of the present disclosure provide an accurate lifetime prediction model of a switching device (inverter/converter) in a circuit by establishing a correlation between aging and dynamic SOA. This dynamic SOA sets up a new model parameter and quantifies the associated changes in model outcomes.

### A Case Study Showing How Reduced SOA Can Reduce Availability

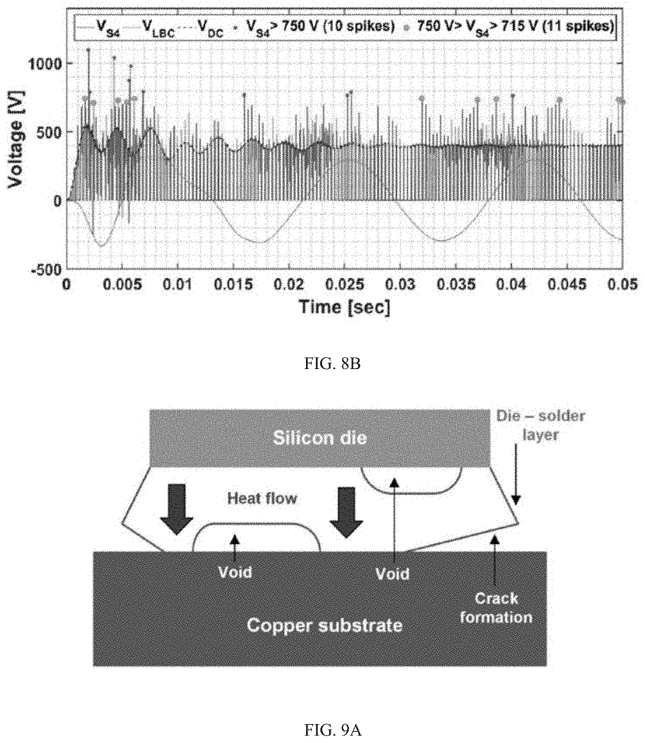

A grid connected converter circuit, as shown in FIG. 8A, often experiences accidental over voltage due to lightning and surges, different faults, inductive switching transients caused by switching OFF large inductive loads, and/or energizing capacitor banks. In addition, stray inductance in a circuit as well as the device/circuit parasitic inductance contribute to overshoot, ringing and impulsive over voltages of power devices in switching applications. For example, as shown in FIG. 8B, despite having a sufficiently large dc link capacitor, the supply line impedance along with the circuit/device stray and parasitic inductances cause considerable voltage spikes at the dc bus during inverter operation. These voltage spikes appear across the switches (e.g., IGBT), and thus, these switches experience accidental over voltage than they were originally intended for. Importantly, a healthy (new) switch (e.g., IGBT) may override multiple overstressed situations, but an aged device is less likely to do so since the SOA goes down with higher aging. For instance, let us consider a switch (S₄) with two aging conditions, and they have safe operating voltages of 750 V (new) and 715 V (aged), respectively. According to the simulation results in FIG. 8B, switch S4 experiences considerable number of voltage spikes within three 60 Hz cycles. Twenty-one (21) of these incidents are higher than 715 V meaning they will exceed the maximum safe operating voltage of the aged device, whereas the healthy switch only experiences ten (10) overvoltage situations. Therefore, the probability of happening a failure is more than twice for an aged device. Thus, dynamic monitoring using the methods described herein and dynamic updating of a SOA can reduce device failure.

### The Relationship Between Aging and Dynamic SOA

A. Why Aging Reduces Maximum Safe Operating Voltage:

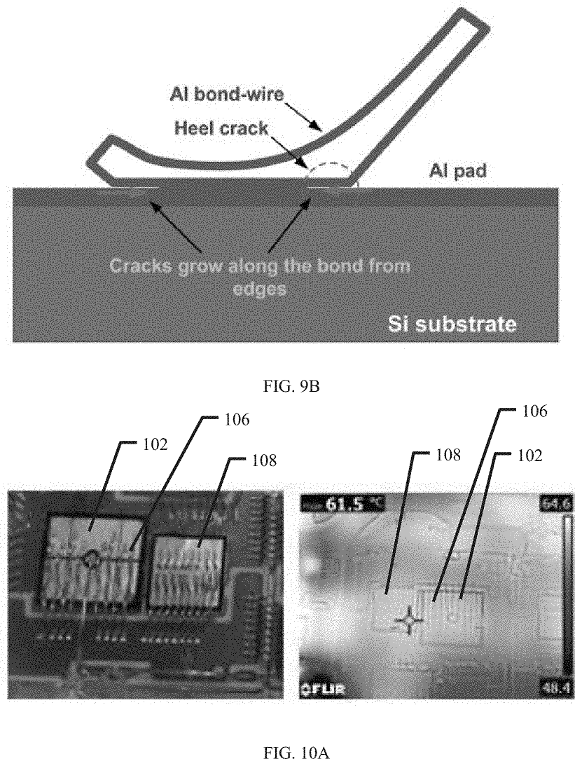

Power semiconductor devices (IGBTs and MOSFETs) are subjected to repetitive power and thermal stresses in normal operation. As shown in FIGS. 9A-9B, cracks and voids in the die-attach layer (the die solder layer) between the Si and Cu die and at the bond wire and chip interface are formed because of the differences in coefficient of thermal expansions (CTEs) in different materials/layers, resulting in bond-wire lift-off. Reduced number of bonded bond-wires, cracks, and voids impede the heat dissipation throughout the device, and thus thermal impedance, as well as junction temperature will increase. Furthermore, increase in the junction temperature could induce hot spots and excess heat in the affected areas of the power devices. This trapped heat will accelerate the cascading effect of impact ionization, which will reduce the device's safe operating voltage and SOA. Impact ionization is a carrier multiplication process by which more electron-hole pairs are generated due to strong Coulombic interactions between charge carriers when a reverse voltage exceeding the critical electric field is applied. This process is cascaded very quickly in a chain-reaction type manner, producing a large number of free electrons and thus a huge current. A substantial amount of power is dissipated across the device resulting in the destruction of the device. Moreover, the localized electric field is increased in the device due to the cracks and voids formation that may lead to accelerated impact ionization as well.

Besides forming voids, cracks etc., other morphological surface defects such as initial solder microstructure, reconstruction of aluminum surface and substrate metallization, and intermetallic compounds are formed while the device undergoes aging. Morphological and crystallographic surface defects can cause premature reverse breakdown due to the localized enhancement of electric fields.

### B. Why Aging Reduces Maximum Safe Operating Current:

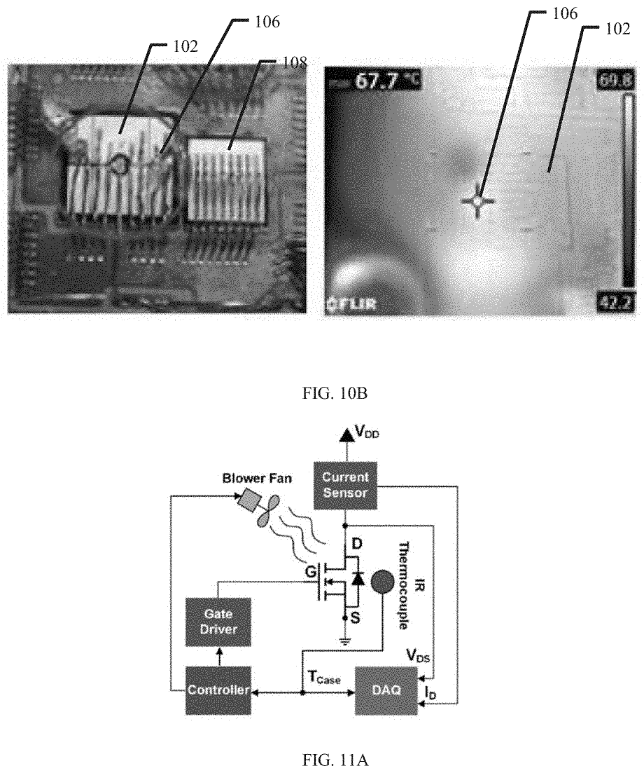

The reduction in the maximum safe operating current (and as a result SOA) can be understood from the bond-wire lift-off related aging in an IGBT module 102. Aging causes damage to bond-wires 106 and introduce current crowding leading to an increase in the substrate temperature (shown in FIGS. 10A-10B, FIG. 10A showing a healthy device and FIG. 10B showing an aged device). The resultant fewer number of bond-wires needed to carry the rated current causes the actually carried current to be higher than that of a healthy module.

Therefore, the rated current (and SOA) needs to be adjusted to a lower magnitude to keep the devices in a healthy state. Otherwise, this overstress situation will increase the likelihood of additional bond-wire lift-offs, heel crack, and even cascaded device failure.

### Accelerated Aging Procedure

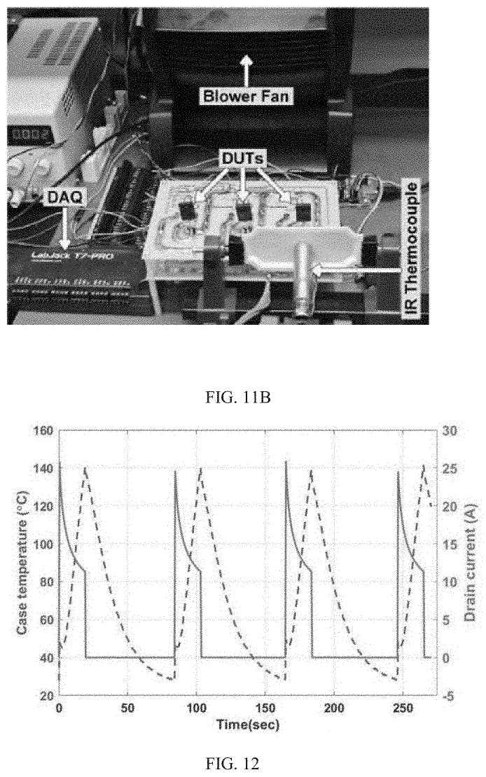

An accelerated aging station is shown in FIGS. 11A-11B (schematically and photographically, respectively) which was used to carry out active power cycling of power devices to investigate dynamic SOA. Using active power cycling, electro-thermal stresses were applied to four N-channel power MOSFETs (M₁, M₂, M₃ and M₄) with similar characteristics (600V-50A). The temperature variation of the device is induced by the loss generated due to the switching of the load current through the device (shown in FIG. 12). The applied thermal gradients, number of power cycles and resultant increase in the device ON-resistance (Δ R_{DS(ON)}) are summarized in Table 2 (below).

TABLE 2

| MOSFET | ΔT | N_{cycles} | Δ R_{DS(ON)} |
|---|---|---|---|
| M₁ | 80° C. | 13100 | 41.77% |
| M₂ | 80° C. | 9525 | 40.72% |
| M₃ | 80° C. | 6350 | 32.81% |
| M₄ | 110° C. | 10667 | 55.19% |

For instance, MOSFET-2 (M₂) was power cycled with a temperature gradient of 80° C. where maximum and minimum temperature thresholds were maintained at 110° C. and 30° C., respectively. The aging procedure was continued for 9525 cycles, and it was found that the R_{DS(ON)} increased from 50.93 mΩ to 71.67 mΩ leading to 40.72% change in value. R_{DS(ON)} of a MOSFET is considered to be the most significant aging precursor, especially for package related aging such as wire-bond lift offs, cracks and voids in the surface, solder fatigues and so on. Throughout this disclosure, any rise in R_{DS(ON)} will refer to the severity of device degradation although the direct relationship between device's aging level and R_{DS(ON)} can vary. A data acquisition system (DAQ) was used to continuously monitor V_{DS}, I_{D} and case temperature (T_{Case}), and an IR thermocouple was used to measure the device case temperature. A cooling fan was activated to cool the DUT quickly during OFF state. Similar techniques can be used in aging IGBTs.

### Experimental Set-up and Results: Characterizing Maximum Safe Operating Voltage as a Function of Aging

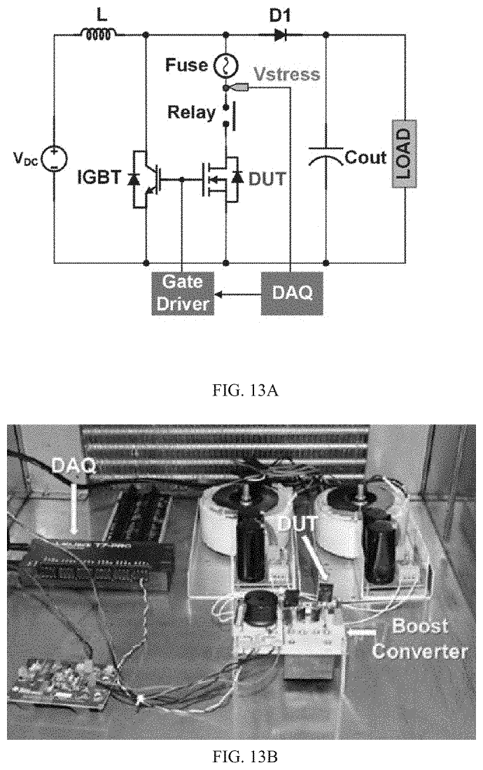

FIG. 13A and 13B show, respectively, a schematic diagram and a photograph of an initial experimental setup of a destructive test in order to characterize a device's maximum operating voltage as a function of its aging. Voltage above the device's rated operating voltage boundary was applied to induce damage, and it was done by placing the switch at the low-switch side of a boost converter with proper protection circuit (see FIG. 13A). A 1200 V IGBT was used as a controller switch to induce this high voltage. The DUT (e.g., a MOSFET in this case, or IGBT in other cases) was connected in series with a fuse and a relay (which is maintained normally open) and this combined branch was connected in parallel with the IGBT to induce high voltage. The voltage stress above the rated operating voltage of 600 V (from datasheet) was applied on the DUT with an incremental step of 5 V by closing the relay. The relay was closed for 100 ms at each voltage level. When the device enters the breakdown voltage region, a large current starts flowing from the drain to the source, which is disrupted by the fuse to protect the overall converter.

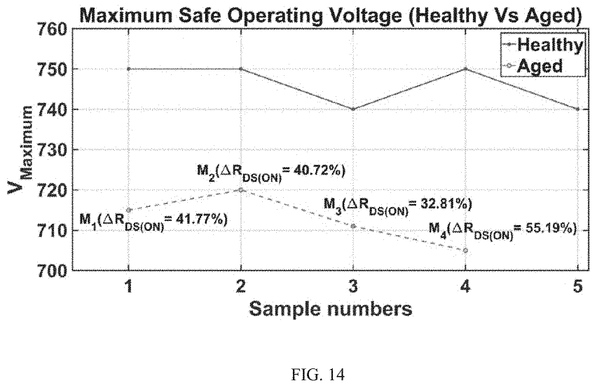

Five healthy and four aged MOSFETs (M₁, M₂, M₃ and M₄) with known aging level were tested and all of them enter into their breakdown region at levels significantly higher than their rated voltage. This is due to the fact that the power semiconductor device ratings are chosen conservatively, meaning a power device may ride through several abnormal conditions. The corresponding experimental results have been shown in FIG. 14. The top line shows the variation in maximum safe operating voltages for new MOSFETs and the bottom line shows the same for aged MOSFETs. It clearly shows that the aged MOSFETs suffer from early failures, and the variation in maximum safe operating voltages (between healthy and aged MOSFETs) was close to 40 V. SiC MOSFETs and Si IGBTs will exhibit similar patterns.

In summary, the present disclosure demonstrates how the safe operating area (SOA) of power semiconductor devices is impacted by aging and aging can be determined by examining the device by ultrasound to find evidence of bond-wire lift-off or other damage/defects. The experimental results show that SOA of a power semiconductor device goes down with aging, and this observation explains why the reliability of an entire circuit exponentially drops with degradation inside the device. Therefore, by knowing the level of aging, we can determine the dynamic SOA of the device and estimate the remaining life of it accurately, and this will allow for scheduled maintenance of any high-power converter. This capability enables reduction in maintenance and operational cost by ensuring higher availability.

A description of certain embodiments of the invention is submitted herewith as Attachment A, the paper draft titled, “Dynamic Safe Operating Area (SOA) of Power Semiconductor Devices” and Attachment B, the paper draft titled, “Detection of Bond-wire lift-off in IGBT Power Modules Using Ultrasound Resonators” which is hereby incorporated by reference in its entirety.

Referring to the Figures generally and with reference to the operating principles discussed above, exemplary methods for in-situ and nonintrusive detection of one or more of bond-wire lift-off or surface degradation in a power switching device include the following steps. Initially, it should be noted that this method can be performed on IGBTs, MOSFETS, or other power switching components.

One step includes transmitting an ultrasonic soundwave from at least one transmitter (e.g., a transducer 108). The at least one transmitter is adapted and configured to transmit the ultrasonic soundwave 110 such that the ultrasonic soundwave contacts at least one insulated-gate bipolar transistor module 102. And, the at least one transmitter is adapted and configured to be controlled by a controller (not shown). The controlled can be any suitable controller and can be, for example, a microcontroller, ASIC, or the like. The controller can include memory with instructions which are then executed to control the components described herein to carry out the steps and functions of the components and method described herein.

The transmitted ultrasonic wave 112 comes into contact with one or more components of one or more IGBT modules 102 or other modules to be measured for aging related reductions in performance (e.g., MOSFET, diode 104, substrate, bond-wire 106, etc.). A portion of the ultrasonic wave is reflected and/or induces resonance and/or sympathetic resonance (e.g., in bond-wires 106). The method includes receiving, using at least one receiver (e.g., a separate transducer 108), this reflected or resonant soundwave 112 from the component(s) (e.g., at least one insulated-gate bipolar transistor module). In the case of a reflected soundwave, the received soundwave is a portion of the transmitted ultrasonic soundwave. The at least one receiver 108 is adapted and configured to output a signal to the controller corresponding to received soundwaves. The output can be the result of a piezoelectric output from the transducer 108 of the receiver. The controller receives the signal using any suitable data acquisition technique known to one of skill in the art.

The controller then determines the frequency and amplitude of the received soundwaves based on the data acquired using any suitable data analysis technique known to one of skill in the art in signals analysis. This happens automatically based on the instructions stored on and executed by the controller to operate on the acquired data which is also stored in memory of the controller.

The method further includes comparing at least one of the frequency of the received soundwaves or the amplitude of the received soundwaves to known base characteristics for a new/healthy component or device (e.g. IGBT module) to determine a state of health for the measured component and/or a power switching device including the component. The known base characteristics for a device or component can be measured using the testing techniques described herein and stored in memory of the controller allowing for the controller to make the comparison. Alternatively, the base characteristics can be measured upon initial use of the controller and stored in memory as the base characteristics of a new/healthy device. This allows subsequent measurements to be compared against the base/initial measurements.

This process can be repeated for individual components (e.g., individual IGBTs) within a power switching device. This can be accomplished using the techniques previously described herein, including but not limited to, time delayed measurement, use of individual transducers 108 or transmitter and receiver pairs per component, or the like.

The method can further include determining a difference between the amplitude of the received soundwaves and known amplitude of received soundwaves for a new/healthy component (e.g., IGBT 102) and updating a known safe operating area SOA for a new/healthy component by a factor corresponding to the determined difference in amplitude to generate an updated SOA for the component. This can be accomplished, for example, by the controller taking the values of a base/initial SOA and multiplying it by a factor corresponding to the decrease in the measured amplitude from the base/initial amplitude value for the component or device stored in memory. The SOA can otherwise be updated, e.g., according to a schedule, function, or the like, based on experimental determinations for a particular device or component using the experimental producers described above. The method can further include estimating a remaining life of a power switching device including the component being measured based on the difference between the amplitude of the received soundwaves and known amplitude of received soundwaves for a new/healthy component and based on the updated SOA (e.g., dynamic SOA) for the component or device. Again, the controller carries out this function by applying a function, factor, or the like to modify known values based on currently measured values and/or in view of the current state of the dynamic SOA.

The method can further include periodically transmitting, receiving, and updating the SOA and/or estimated life remaining. The period can be as frequently as multiple times a second or as infrequently as daily, monthly, or yearly. Depending on the application of the apparatus and method described herein, the controller can be used to modify the period appropriately.

The method can further include controlling operation of a power switching device (e.g., an inverter/converter 114) including the component/device being measured, using the controller, such that the component/device operates within the updated safe operating area. For example, the controller can limit current to one or more collectors of one or more insulated-gate bipolar transistor modules of the power switching device to maintain operation within the updated safe operating area. The current can be limited using any suitable protection circuit or technique. For example, the controller can control a variable resistor or select between circuits of varying resistance such that the voltage across the resistor or selected circuit is applied to a small auxiliary transistor that progressively steals or diverts base current from the power device as it passes excess collector current. Alternatively, the controller can communicate with other equipment to cause the device to be taken offline or to cause the selection of an alternative circuit that does not include the device the controller is monitoring. The controller can communicate using any suitable equipment and protocols for wired and/or wireless communication (e.g., over the internet, through a cellular network, Bluetooth, or the like).

The method can further include determining a difference between the amplitude of the received soundwaves from the component/device and known amplitude of received soundwaves for a new component/device and estimating a remaining life of a power switching device including the insulated-gate bipolar transistor module based on the determined difference. Again, this can be determined by the controller applying a factor, function, or schedule to a known value based on the difference determined by the controller.

The method can further include receiving, using at least one receiver, resonate soundwaves from one or more components (e.g., an IGBT 102, bond-wire 106, or the like) resonating as a result of transmitted ultrasonic wave exiting the one or more components. The method then includes determining, using the controller and based on the received resonate soundwaves, one or more harmonic or sub-harmonic frequencies of the one or more components. The harmonic or sub-harmonic frequencies can be determined using any suitable signal analysis technique. The method can further include comparing the determined one or more harmonic or sub-harmonic frequencies to known corresponding harmonic or sub-harmonic frequencies for a new/healthy component/device (e.g., IGBT 102) to determine one or more of a shift in frequency for the determined one or more harmonic or sub-harmonic frequencies or a reduction in amplitude for the received resonate soundwaves at one or more of the harmonic or sub-harmonic frequencies. Based on the comparison the controller can estimate an age of a power switching device including the integrated-gate bipolar transistor module or update a safe operating area for the power switching device. This can be accomplished by using a factor, function, schedule (e.g., experimental), look up table, or the like applied by the controller.

In some embodiments, the method is performed while the device/component is in operation. In other words, the at least one transmitter 108 transmits the ultrasonic soundwave and the at least one receiver 108 receives the reflected soundwave while the device 114/component (e.g., IGBT 102) is in operation.

The description herein is merely exemplary in nature and, thus, variations that do not depart from the gist of that which is described are intended to be within the scope of the teachings. Moreover, although the foregoing descriptions and the associated drawings describe example embodiments in the context of certain example combinations of elements and/or functions, it should be appreciated that different combinations of elements and/or functions can be provided by alternative embodiments without departing from the scope of the disclosure. Such variations and alternative combinations of elements and/or functions are not to be regarded as a departure from the spirit and scope of the teachings.

What is claimed is:

1. A method for in-situ and nonintrusive detection of one or more of bond-wire lift-off or surface degradation in insulated-gate bipolar transistor modules of a power switching device, the method comprising:
transmitting an ultrasonic soundwave from at least one transmitter, the at least one transmitter adapted and configured to transmit the ultrasonic soundwave such that the ultrasonic soundwave contacts at least one insulated-gate bipolar transistor module, the at least one transmitter being adapted and configured to be controlled by a controller;
receiving, using at least one receiver, a reflected soundwave from the at least one insulated-gate bipolar transistor module, the reflected soundwave being a portion of the transmitted ultrasonic soundwave, the at least one receiver being adapted and configured to output a signal to the controller corresponding to received soundwaves;
using the controller to determine the frequency and amplitude of the received soundwaves; and
comparing at least one of the frequency of the received soundwaves or the amplitude of the received soundwaves to known base characteristics for a new insulated-gate bipolar transistor module to determine a state of health for a power switching device including the insulated-gate bipolar transistor module being measured for at least one of bond-wire lift-off or surface degradation.

2. A method in accordance with claim 1, further comprising determining a difference between the amplitude of the received soundwaves and known amplitude of received soundwaves for a new insulated-gate bipolar transistor module and updating a known safe operating area for a new insulated-gate bipolar transistor module by a factor corresponding to the determined difference in amplitude to generate an updated safe operating area for the insulated-gate bipolar module being measured for bond-wire lift-off.

3. A method in accordance with claim 2, further comprising estimating a remaining life of a power switching device including the insulated-gate bipolar transistor module based on the difference between the amplitude of the received soundwaves and known amplitude of received soundwaves for a new insulated-gate bipolar transistor module and based on the updated safe operating area for the insulated-gate bipolar module being measured for bond-wire lift-off.

4. A method in accordance with claim 2, further comprising controlling operation of a power switching device including the insulated-gate bipolar transistor module, using the controller, such that the power switching device operates within the updated safe operating area.

5. A method in accordance with claim 4, wherein the controller limits current to one or more collectors of one or more insulated-gate bipolar transistor modules of the power switching device to maintain operation within the updated safe operating area.

6. A method in accordance with claim 1, further comprising determining a difference between the amplitude of the received soundwaves from the insulated-gate bipolar transistor and known amplitude of received soundwaves for a new insulated-gate bipolar transistor module and estimating a remaining life of a power switching device including the insulated-gate bipolar transistor module based on the determined difference.

7. A method in accordance with claim, further comprising:
receiving, using at least one receiver, resonate soundwaves from one or more components of the at least one insulated-gate bipolar transistor module resonating as a result of transmitted ultrasonic wave exiting the one or more components; and
determining, using the controller and based on the received resonate soundwaves, one or more harmonic or sub-harmonic frequencies of the one or more components.

8. A method in accordance with claim 7, further comprising comparing the determined one or more harmonic or sub-harmonic frequencies to known corresponding harmonic or sub-harmonic frequencies for a new integrated-gate bipolar transistor module to determine one or more of a shift in frequency for the determined one or more harmonic or sub-harmonic frequencies or a reduction in amplitude for the received resonate soundwaves at one or more of the harmonic or sub-harmonic frequencies, and based on the comparison estimating an age of a power switching device including the integrated-gate bipolar transistor module or updating a safe operating area for the power switching device.

9. A method in accordance with claim 1, wherein the at least one transmitter transmits the ultrasonic soundwave and the at least one receiver receives the reflected soundwave while the integrated-gate bipolar transistor is in operation.

10. A method in accordance with claim 1, wherein the at least one transmitter transmits the ultrasonic soundwave, the at least one receiver receives the reflected soundwave, the controller determines the frequency and amplitude of the received soundwaves, and a comparison is made between at least one of the frequency of the received soundwaves or the amplitude of the received soundwaves to known base periodically.

11. A method in accordance with claim 1, wherein the at least one transmitter and the at least one receiver are transducers.

12. A method in accordance with claim 11, wherein the at least one transmitter and the at least one receiver are a single transducer per integrated-gate bipolar transducer module.

13. A method in accordance with claim 11 wherein the at least one transmitter consists of a single transducer for transmitting only, and the at least one receiver comprises a plurality of transducers for receiving only.

14. A method in accordance with claim 13 wherein plurality of transducers for receiving only measure a plurality of integrated-gate bipolar transducers using a single transmitted ultrasonic soundwave.

15. A method in accordance with claim 11 wherein the transducers are one of piezoelectric transducers, capacitive transducers, magnetostriction transducers, or microelectromechanical systems transducers.

16. A method in accordance with claim 1, wherein the at least one transmitter is further adapted and configured to transmit an ultrasonic wave at a frequency and magnitude to cause sympathetic resonance within at least one component of the at least one insulated-gate bipolar transistor module; and wherein the at least one receiver receives return soundwaves from the at least one component of the at least one insulated-gate bipolar transistor module, the return soundwaves resulting from at least the sympathetic resonance of the at least one component.

17. A method in accordance with claim 16, wherein the at least one component comprises a plurality of bond wires of a single insulated-gate bipolar transistor module.

18. A method in accordance with claim 16, wherein the at least one component comprises a plurality of bond wires directly coupled to an insulated-gate bipolar transistor ship of a single insulated-gate bipolar transistor module.

19. A method in accordance with claim 16, wherein the at least one component comprises a plurality of bond wires not directly coupled to an insulated-gate bipolar transistor chip but still contained within a single insulated-gate bipolar transistor module.

20. A method in accordance with claim 1, wherein all of the at least one transmitters are adapted and configured to transmit the ultrasonic soundwave at a frequency of substantially 25 megahertz or substantially 35 megahertz.
